(19) United States
(12) Patent Application Publication
(10) Pub. No.: US 2014/0230886 A1
(43) Pub. Date: Aug. 21, 2014

(54) Solar Panel Assembly With A Mounting Structure

(71) Applicants: Mark F. Werner, LaSalle (CA); Zachary A. Marten, Rochester Hills, MI (US); Peter M. Szadyr, Lake Orion, MI (US); Ryan R. Warpup, Troy, MI (US)

(72) Inventors: Mark F. Werner, LaSalle (CA); Zachary A. Marten, Rochester Hills, MI (US); Peter M. Szadyr, Lake Orion, MI (US); Ryan R. Warpup, Troy, MI (US)

(21) Appl. No.: 14/346,762

(22) PCT Filed: Oct. 12, 2012
(86) PCT No.: PCT/US12/59964

§ 371 Date: Mar. 24, 2014

Related U.S. Application Data
(60) Provisional application No. 61/547,147, filed on Oct. 14, 2011.

(51) Int. Cl. H01L 31/042

(52) U.S. Cl. CPC H01L 31/0422; H02S 20/00
USPC 136/251

(57) ABSTRACT

A solar assembly is provided for harnessing solar rays and generating electricity. The solar assembly includes at least one vertical leg extending in a vertical direction and having an upper attachment end. The assembly also includes at least one north-south rail and a plurality of east-west rails extending generally transversely to the north-south rail. A curved member interconnects the vertical leg with the north-south rail and extends through an arcuate shape. The solar assembly also includes a plurality of generally flat arrays of solar panels, such as photovoltaic panels, are coupled to the east-west members. The orientation of the solar panels relative to a base or the ground is dependent on the location along the curved member of the connection with the vertical leg.

### CROSS-REFERENCE TO PRIOR APPLICATION

This U.S. National Stage Patent application claims the benefit of International Application Serial No. PCT/US2012/059964 filed Oct. 12, 2012 entitled “Solar Panel Assembly With A Mounting Structure,” which claims the benefit of U.S. Provisional Patent Application Ser. No. 61/547,147 filed Oct. 14, 2011, entitled “Mounting Structure,” the entire disclosures of the applications being considered part of the disclosure of this application and hereby incorporated by reference.

### BACKGROUND OF THE INVENTION

1. Field of the Invention

The subject invention is related to a solar panel assembly, and more precisely to a solar panel assembly including a mounting structure for solar panels.

2. Description of the Prior Art

Solar power is becoming an increasingly popular alternative to fossil fuels for generating electricity. In general, solar power generators harness the potential energy of solar radiation and convert that potential energy into electricity. Some solar power generators utilize an array of mirrors which reflect and concentrate light into a small area. Heat from the reflected and concentrated light is then used to generate electricity in a manner similar to conventional power plants. Another type of solar power generator is a photovoltaic (PV) cell, which harnesses solar rays and directly converts solar radiation into electricity.

PV cells are typically arranged in one or more arrays which are supported by a mounting structure. For maximum effectiveness, the PV arrays must remain outdoors, and therefore, the PV arrays and mounting structure must be resistant to a wide range of environmental factors including, for example, high winds, rain, hail and large snow falls. Some mounting structures are designed to automatically reorient the PV arrays to “follow the sun” as it moves through the sky, thereby maximizing the solar rays harnessed. However, such mounting structures may not always be cost-effective. Therefore, most PV panels are mounted on a stationary mounting structure which orients the PV panels at a predetermined angle. While stationary mounting structures may be less costly than sun tracking mounting structures, a certain amount of potential energy is inherently lost due to seasonal changes of the earth's axis relative to the sun.

One type of mounting structure is generally shown in FIGS. 1-3. This mounting structure includes a vertical leg attached to a foundation piling and extending vertically upwardly therefrom. A north-south member is attached to the upper end of the vertical leg, and a pair of angled legs extend at opposite angles between the vertical leg and the north-south member to provide additional support for the north-south member. The angled legs have different lengths from one another such that the north-south member is oriented at a predetermined angle relative to the ground. A plurality of east-west members extend transversely to the north-south member, and the PV arrays are coupled to the east-west members. Because the angled legs of the mounting structure are not adjustable, the mounting structure is not easily adjustable to re-orient the PV arrays relative to the ground.

There remains a significant and continuing need for an improved mounting structure which is cheaper and easier to fabricate without compromising its ability to resist the outdoor environmental forces to which it is likely to be subjected.

### SUMMARY OF THE INVENTION

At least one aspect of the present invention provides for a solar assembly for harnessing solar rays and generating electricity. The solar assembly includes a mounting structure with at least one leg extending generally upwardly to an upper attachment end. The mounting structure also includes a north south rail and a plurality of east-west rails which extend generally transversely to the north-south rail and are spaced from one another along the length of the north-south rail. A plurality of generally flat arrays of solar panels are coupled to the east-west rails and supported by the mounting structure. The north-south rail is coupled to the leg via a curved member which extends through an arcuate shape between spaced ends, each of which is coupled to the north-south rail. As such, the curved member is coupled to the upper attachment end of the leg at a location between the spaced ends.

Because of the curvature of the curved member, the orientations of the PV arrays relative to the base are dependent upon the location along the curved member of its connection to the upper attachment end of the leg. As such, mounting structures may be mass produced and individually configured to orient their respective arrays at different angles relative to the bases. This is advantageous because it may be desirable to orient the arrays of solar assemblies in different geographical locations to optimize power produced in each location. For example, the further away from the earth's equator that the solar assembly is going to operate, it may be desirable to orient the arrays at steeper angles. In other words, each mounting structure may be individually configured to optimize the angles of the PV arrays in a particular geographical location. This leads to significant cost savings through economies of scale. In contrast, many other known mounting structures are built in the factory to orient the PV arrays at a single, non-adjustable, angle relative to the base and significant and costly changes must be made to the manufacturing equipment to produce mounting structures that support PV arrays at different angles relative to the base.

The mounting structure of this aspect of the present invention is also advantageous because it includes fewer components than other known mounting structures. This leads to, among other things, material savings, weight savings, and labor savings during the assembly of the mounting structure in the field. Additionally, the mounting structure has very few joints which leads to improved durability. Even further, the arcuate shape of the curved member improves the structural integrity of the mounting structure. Depending on the type of connector employed to connect the north-south rail to the leg, the mounting structure may also be easier to adjust than other known mounting structures.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a perspective and elevation view of a known mounting structure;

FIG. 2 is a side view of the known mounting structure of FIG. 1;

FIG. 3 is a perspective and fragmentary view of the known mounting structure of FIG. 1 and showing the interconnections of the vertical member, the angled members, the bracket, and the foundation piling;

FIG. 4 is a perspective and elevation view of the first exemplary solar assembly;

FIG. 5 is a side view of the solar assembly of FIG. 4;

FIG. 6 is another perspective and elevation view of the solar assembly of FIG. 4;

FIG. 7 is a perspective and elevation view of a second exemplary solar assembly;

FIG. 8 is a perspective and elevation view of a mounting structure of a third exemplary solar assembly;

FIG. 9 is a perspective and fragmentary view of the third exemplary mounting structure and showing the interconnection of a curved member and a north-south rail; and

FIG. 10 is a perspective and fragmentary view of the third exemplary mounting structure and showing the interconnection of the curved member and the vertical leg.

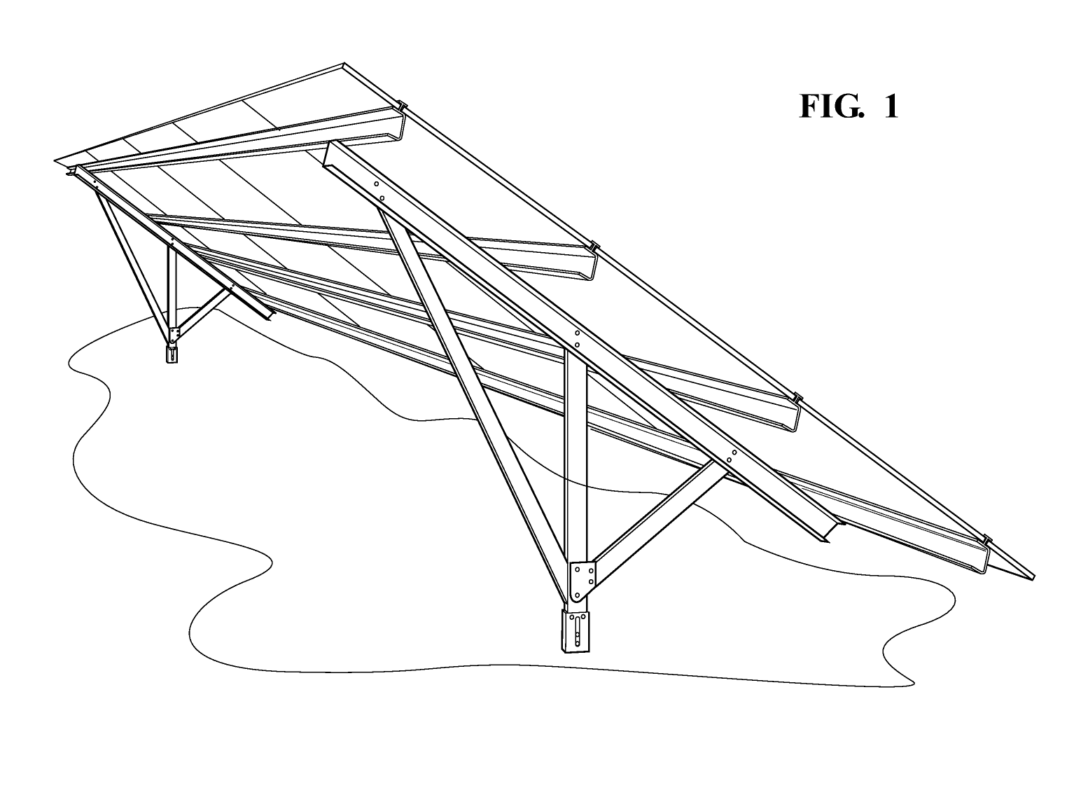

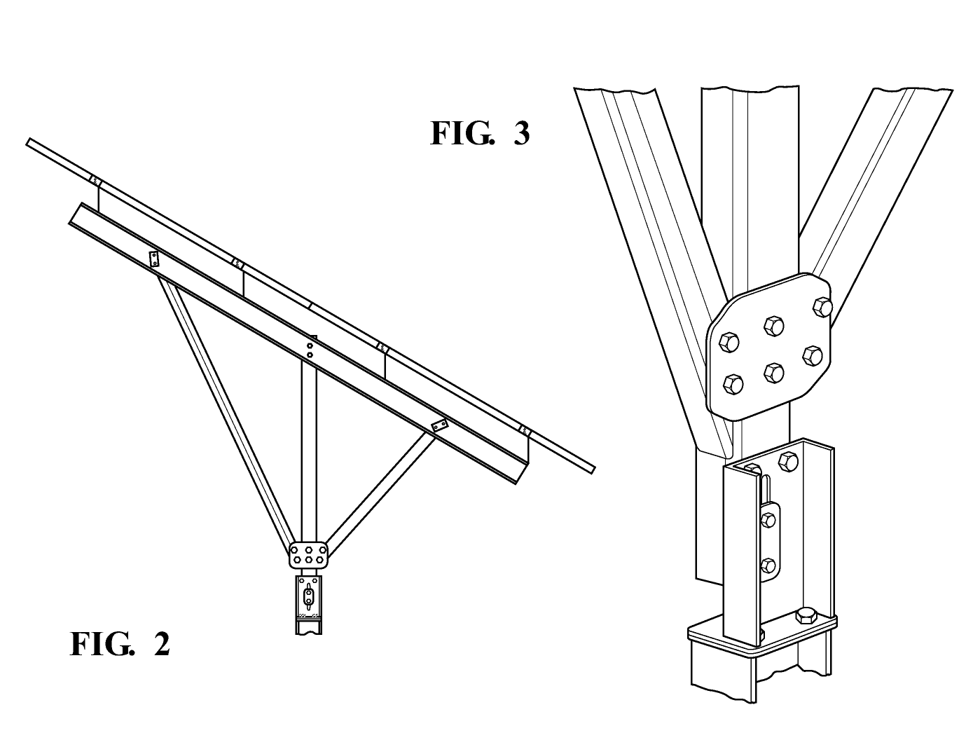

### DESCRIPTION OF THE ENABLING EMBODIMENT

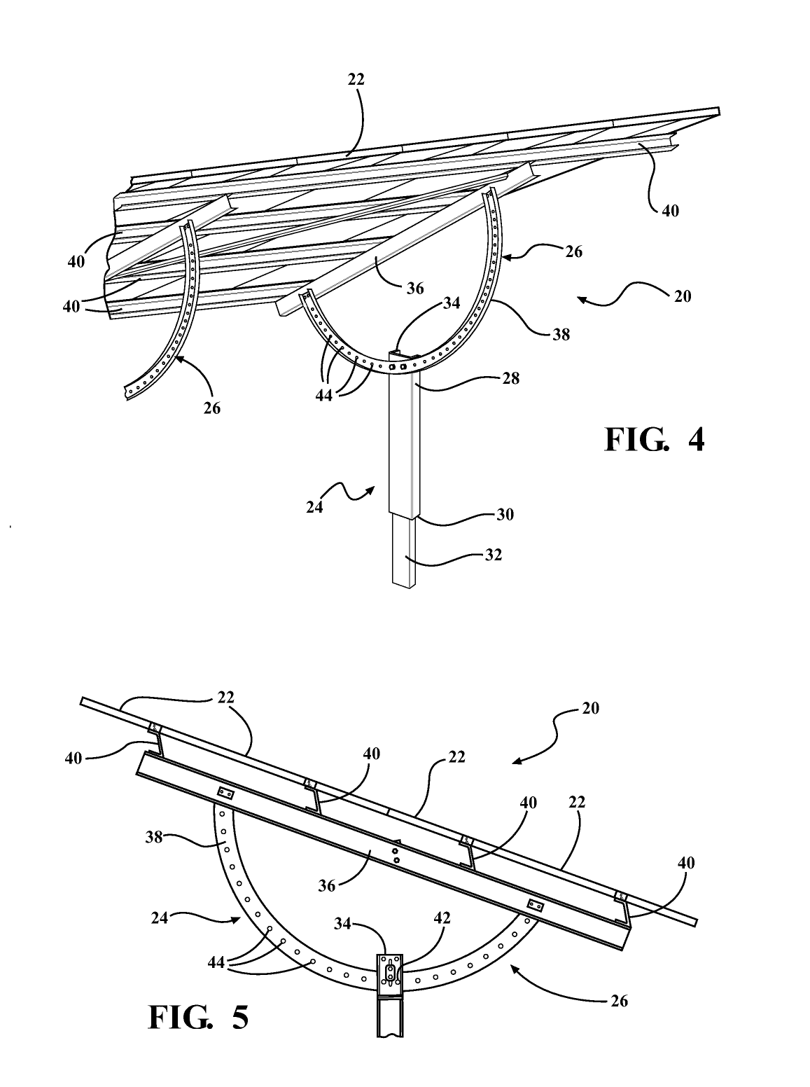

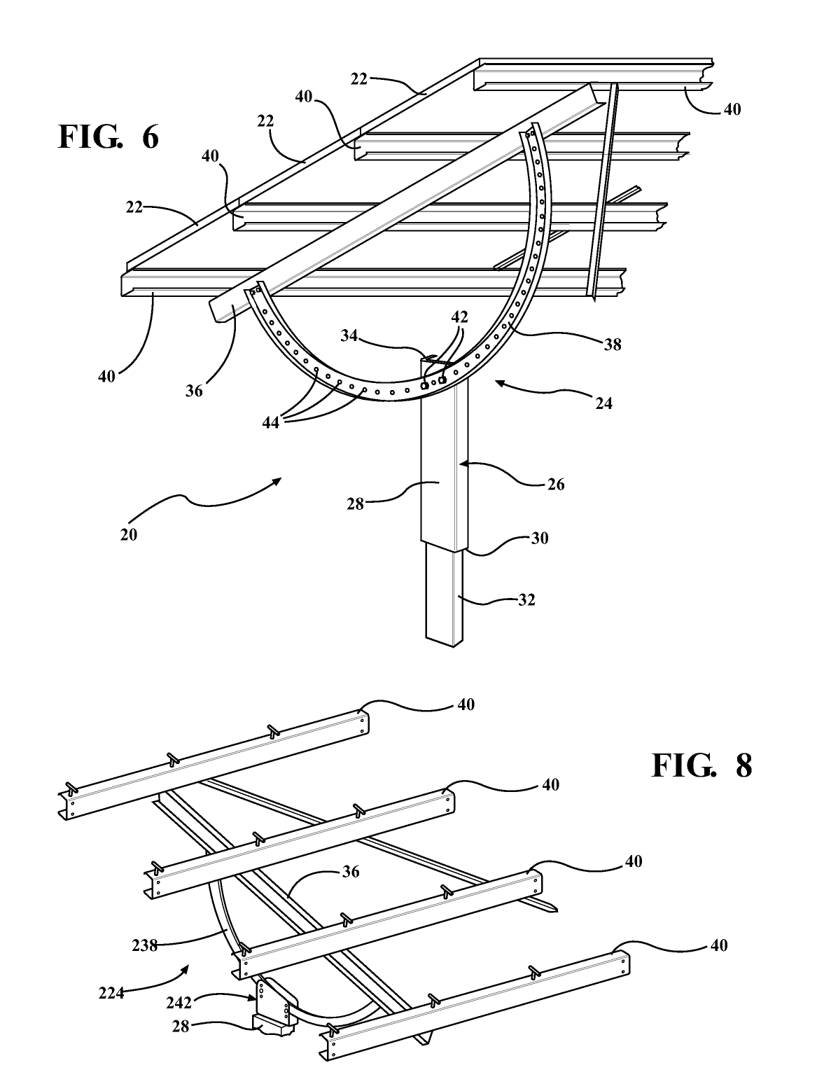

Referring to the Figures, wherein like numerals indicate corresponding parts throughout the several views, a first exemplary embodiment of a solar assembly 20 for harnessing potential energy from solar rays and generating electricity is generally shown in FIGS. 4-6. The solar assembly 20 includes a plurality of solar panels arranged in a plurality of arrays 22 which are supported by a stationary (i.e., non-tracking) mounting structure 24. In the exemplary embodiment, the solar panels are photovoltaic (PV) cells that are configured to receive solar radiation and convert it into electrical power. However, it should be appreciated that any other type of solar panel capable of converting potential energy from solar rays into electricity or into any other form of useable energy could alternately be employed.

Referring now to FIG. 5, the mounting structure 24 of the first exemplary embodiment includes a plurality of sub-assemblies 26 spaced from one another in a lateral direction, which is hereinafter referred to as an “east-west direction”. Each sub-assembly 26 includes a vertical leg 28 which extends vertically upwardly from a base attachment end 30 coupled to a foundation piling 32 in a base (such as the ground or the roof of a building) to an upper attachment end 34. Each sub-assembly 26 also includes a north-south rail 36 (or any other type of member) which extends in a longitudinal direction and is connected to the vertical leg 28 via a curved member 38. A plurality of east-west rails 40 (or any other type of member) are coupled to the north-south rails 36 of adjacent sub-assemblies 26 and extend generally transversely between two or more north-south rails 36. The east-west rails 40 are spaced from one another along the length of the north-south rails 36 and all extend in generally parallel relationship with one another. The east-west rails 40 could extend through any length and could interconnect any desirable number of sub-assemblies 26. The exemplary embodiment includes four east-west rails 40 but it should be appreciated that the mounting structure 24 could include any desirable number of east-west rails 40. In the exemplary embodiment, the north-south members are attached to the curved members 38 and to the east-west rails 40 via mechanical fasteners, such as bolts. However, it should be appreciated that these components could alternately be coupled together through any desirable process, such as other types of mechanical fasteners, spot welding, brazing, adhesives, etc. It should be noted that the north-south rails 36 and east-west rails 40 are referred to by the terms “north-south” and “east-west” respectively because this is the preferred directions in which they extend in the field so that the PV arrays 22 face generally south in the northern hemisphere or north in the southern hemisphere. However, it should be appreciated that these rails 36, 40 could be oriented in any desirable direction.

The vertical legs 28, north-south rails 36, east-west rails 40, and curved members 38 are all preferably formed of aluminum or steel but could alternately be formed of any desirable metal or non-metallic material. Each of these components is also preferably shaped to have a generally C-shaped cross-section through a roll forming process. Such a process may be particularly advantageous in shaping the curved member 38 because the arcuate shape of curved member 38 may also be formed by roll forming. Additionally, with slight adjustments to the roll forming equipment, the curvature of the curved members 38 being produced can be adjusted. However, it should be appreciated that these components could be shaped to any desirable cross-section through any suitable process.

As best shown in FIG. 5, the PV arrays 22 are generally flat and, because the exemplary north-south members are linearly shaped, are oriented in generally parallel relationship with one another. Although not shown, it should be appreciated that the north-south members could alternately be curved which would angle the PV arrays 22 both relative to the base and to one another. The PV arrays 22 are preferably coupled to the east-west rails 40 via mechanical fasteners but could be coupled to the east-west rails 40 through any desirable process such as, for example, adhesives, welding or brazing.

Referring still to FIG. 5, the ends of the curved member 38 are spaced from one another along the north-south rail 36, and the curved member 38 is coupled to the upper attachment end 34 of the vertical leg 28 at a location between the spaced ends. Because of the curvature of the curved member 38, the orientations of the PV arrays 22 relative to the base are dependent upon the location along the curved member 38 of its connection to the upper attachment end 34 of the vertical leg 28. As such, the mounting structures 24 may be individually configured to orient their respective PV arrays 22 at different angles relative to the bases. This is advantageous because it may be desirable to orient the PV arrays 22 of solar assemblies 20 in different geographical locations to optimize power produced in each location. For example, the further away from the earth's equator that the solar assembly 20 is going to operate, it may be desirable to orient the PV arrays 22 at steeper angles. In other words, the mounting structure 24 may be mass produced without changes to the manufacturing process, and each mounting structure 24 may be individually configured to optimize the angles of the PV arrays 22 in a particular geographical location. This leads to significant cost savings through economies of scale. In contrast, many other known mounting structures are built in the factory to orient the PV arrays at a single, non-adjustable, angle relative to the base and significant and costly changes must be made to the manufacturing equipment to produce mounting structures that support PV arrays at different angles relative to the base.

The curved members 38 are preferably coupled to the upper-attachment end of the vertical leg 28 through a non-permanent connector 42. For example, in the first exemplary embodiment of FIGS. 4-6, the curved member 38 includes a plurality of sets of apertures 44 spaced from one another along its length. The exemplary connector 42 is a pair of bolts 42 or pins which are configured to couple the upper attachment end 34 to the curved member 38 at any of the sets of apertures 44. As such, a person in the field may easily fasten the curved member 38 to the vertical leg 28 in such a way that the PV arrays 22 are oriented at an optimum angle relative to the base for that particular geographical location, i.e. at an angle that will maximize power generation. Additionally, since the connector 42 is not permanent, the orientations of the PV arrays 22 may be adjusted in the field, for example, between seasons to further increase the energy produced by the solar assembly 20. However, it should be appreciated that the connection between the curved member 38 and the upper attachment end 34 of the vertical leg 28 could be any desirable type of permanent or non-permanent connection.

The first exemplary embodiment of the mounting structure 24 is also advantageous because it includes fewer components than other known mounting structures. This leads to, among other things, material savings, weight savings, and labor savings during the assembly of the mounting structure 24 in the field. Additionally, the mounting structure 24 has very few joints which leads to improved durability. Even further, the arcuate shape of the curved member 38 improves the structural integrity of the mounting structure 24.

The curved member 38 preferably extends through an arc of greater than ninety degrees (90°) and most preferably greater than one hundred and sixty degrees (160°) to provide for a large range of different possible orientations of the PV arrays 22 relative to the base.

Referring now to FIG. 7, a second exemplary embodiment of the solar assembly 120 is generally shown. All of the components of the mounting structure 124 are similar to the first embodiment described above except for the curved member 138. In the second exemplary embodiment, the curved member 138 includes linear sections adjacent each of the spaced ends. This embodiment illustrates that the curvature of the curved member 138 does not have to be constant throughout its length. It should be appreciated that the curved member 138 could have a range of different curvatures and shapes.

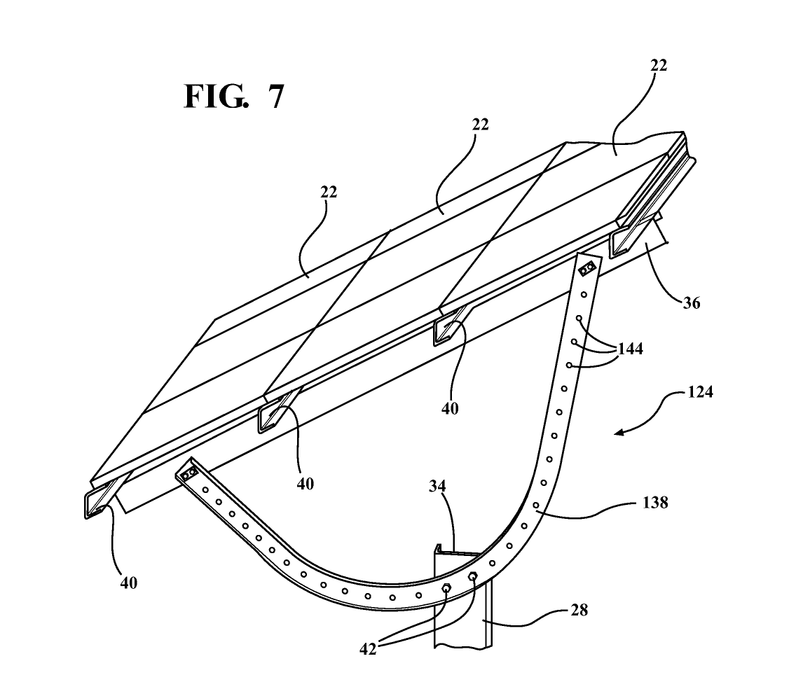

Referring now to FIG. 8, a mounting structure 224 of a third exemplary embodiment of the solar assembly is generally shown. In the third exemplary embodiment, all of the components are similar to the first exemplary embodiment discussed above with the exception of the curved member 238 and the connector 242. Specifically, the curved member 238 of this embodiment has an elongated tubular shape and the connector 242 includes a pair of plates 246 spaced from one another at the upper attachment end 34 of the vertical leg 28. Each plate 246 includes a plurality of back apertures 248 spaced vertically from one another and a plurality of front apertures 250 spaced vertically from one another. In the field, a person may use a pair of pins or bolts 252 to connect the curved member 238 to any of the front apertures 250 and to any of the back apertures 248. Different combinations of the back and front apertures 248, 250 will determine the orientation of the north-south rail 36 and also the PV arrays (not shown in this Figure) relative to the base. In other words, a person may quickly set up the mounting structure 224 such that the PV arrays are oriented at an angle relative to the base that is optimized for a particular geographical location. It should be appreciated that the tubular curved member 238 could alternately be coupled to the vertical leg 28 through a range of different connectors.

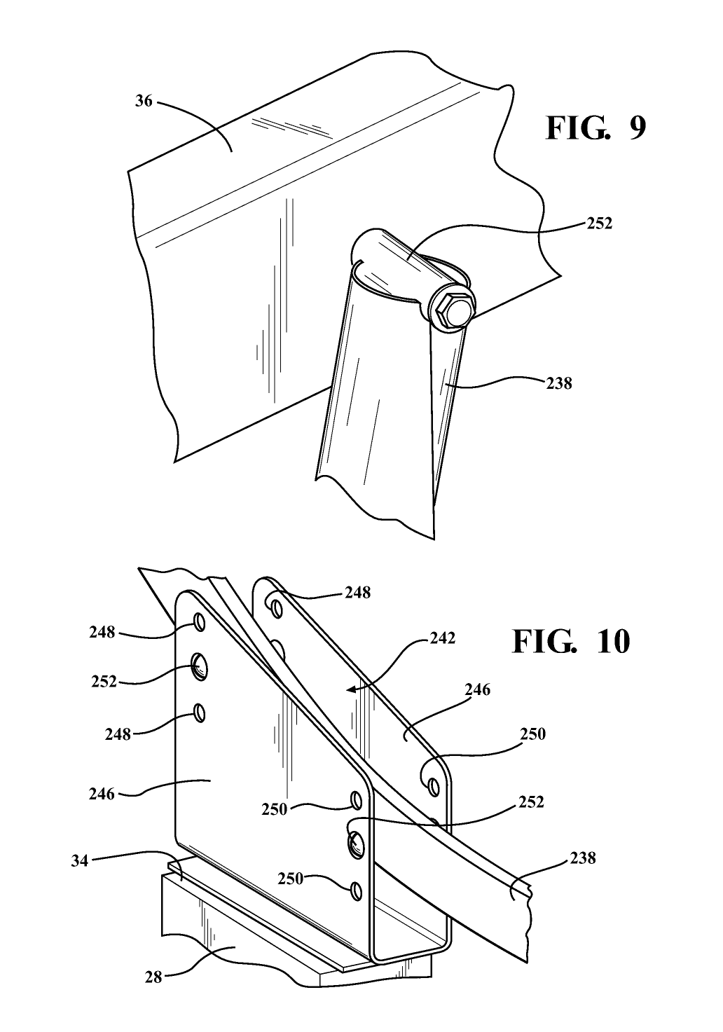

Referring now to FIG. 9, a sleeve 252 is attached to each end of the tubular curved member 238 of the third exemplary embodiment. This sleeve 252 may receive a bolt, a screw, or any other type of fastener to interconnect the tubular curved member 238 with the north-south rail 36. The sleeve 252 is preferably metal-inert gas (MIG) welded to the end of the tubular curved member 238. However, it should be appreciated that the sleeve 252 could be connected to the tubular curved member 238 through, for example, other types of welding, adhesives, brazing, etc. Alternately, other fastening mechanisms could be used to connect the tubular curved member 38 with the north-south rail 36.

Obviously, many modifications and variations of the present invention are possible in light of the above teachings and may be practiced otherwise than as specifically described while within the scope of the appended claims.

What is claimed is:

1. A solar assembly for harnessing solar rays and generating electricity, comprising:
at least one leg extending upwardly and having an upper attachment end;
a north-south rail;
a plurality of east-west rails extending generally transversely to said north-south rail and spaced from one another along the length of said north-south rail, and wherein said east-west rails extend in generally parallel relationship with one another;
a plurality of generally flat arrays of solar panels coupled to said east-west rails; and
a curved member extending through an arcuate shape between spaced ends coupled to said north-south rail, and wherein said curved member is coupled to said upper attachment end of said leg at a location between said spaced ends.

2. The solar assembly as set forth in claim 1 further including at least one connector configured to couple said upper attachment end of said leg more than one location along said curved member and wherein the orientations of said PV arrays is at dependent on the location of the connection between said curved member and said upper attachment end of said leg

3. The solar assembly as set forth in claim 1 wherein said at least one connector is a plurality of mechanical fasteners and wherein said curved member includes at least two sets of apertures spaced from one another and being configured to receive the mechanical fasteners and wherein each set of apertures defines a location for coupling said curved member to said upper attachment end of said leg.

4. The solar assembly as set forth in claim 3 wherein said curved member extends through an arc of greater than one hundred and sixty degrees (160°).

5. The solar assembly as set forth in claim 1 wherein said curved member is generally tubular

6. The solar assembly as set forth in claim 5 wherein said connector includes a pair of plates spaced from one another and at least one mechanical fastener for connecting said curved member to said plates

7. The solar assembly as set forth in claim 6 further including a sleeve coupled to each end of said curved member

8. The solar assembly as set forth in claim 1 wherein said curved member includes a generally linear section adjacent each of said spaced ends

9. The solar assembly as set forth in claim 1 wherein said north-south rail extends generally linearly

10. The solar assembly as set forth in claim 9 wherein said east-west rails extend generally linearly.
